(19) United States
(12) Patent Application Publication
(10) Pub. No.: US 2007/0264728 A1
(43) Pub. Date: Nov. 15, 2007

(54) Manufacturing method of tunnel magnetoresistive effect element, manufacturing method of thin-film magnetic head, and manufacturing method of magnetic memory

(75) Inventors: Satoshi Miura, Chuo-ku (JP); Takumi Uesugi, Chuo-ku (JP)

Correspondence Address: BUCHANAN, INGERSOLL & ROONEY PC, POST OFFICE BOX 1404, ALEXANDRIA, VA, 22313-1404, US

(73) Assignee: TDK Corporation, Chuo-ku (JP)

(21) Appl. No.: 11/797,635

(22) Filed: May 4, 2007

(30) Foreign Application Priority Data
May 11, 2006 (JP) 132410/2006

(51) Int. Cl. H01L 21/00

(52) U.S. Cl. 438/3; 438/73

(57) ABSTRACT

A manufacturing method of a TMR element having a magnetization fixed layer, a magnetization free layer and a tunnel barrier layer sandwiched between the magnetization fixed layer and the magnetization free layer. A fabricating process of the tunnel barrier layer includes a step of depositing a first metallic material film on the magnetization fixed layer or the magnetization free layer, and a step of oxidizing the deposited first metallic material film under an environment with an impurity concentration of 1E-02 or less.

### PRIORITY CLAIM

This application claims priority from Japanese patent application No. 2006-132410, filed on May 11, 2006, which is incorporated herein by reference.

### BACKGROUND OF THE INVENTION

1. Field of the Invention

The present invention relates to a manufacturing method of a tunnel magnetoresistive effect (TMR) element, a manufacturing method of a thin-film magnetic head having a TMR element, and a manufacturing method of a magnetic memory.

2. Description of the Related Art

The TMR element has a ferromagnetic tunnel junction structure in which a tunnel barrier layer is sandwiched between two ferromagnetic layers, and an anti-ferromagnetic layer is arranged on a surface of one of the ferromagnetic layers, which surface is not contacting the tunnel barrier layer. Thus, one of these ferromagnetic layers functions as a magnetization fixed layer, in which the magnetization of this ferromagnetic layer is hard to move in response to an external magnetic field due to exchange-coupling field with the anti-ferromagnetic layer. The other ferromagnetic layer functions as a magnetization free layer, in which the magnetization is easy to change in response to the external magnetic field. With such a structure, the external magnetic field causes a relative orientation of the magnetization directions of the two ferromagnetic layers to change. The change of the relative magnetization orientation causes the probability of the electrons tunneling through the tunnel barrier layer to vary, to thereby change resistance of the element. Such a TMR element is usable as a read head element that detects intensity of magnetic field from a recording medium, and also applicable to a cell of magnetic RAM (MRAM) as a magnetic memory.

As material of the tunnel barrier layer in the TMR element, amorphous oxide of aluminum (Al) or titanium (Ti) has been generally used as disclosed for example in U.S. Pat. No. 6,710,987.

Recently, there has been proposed a TMR element using a tunnel barrier layer made of crystalline magnesium oxide (MgO). Such TMR element using the tunnel barrier layer of magnesium oxide can have a higher MR ratio (magnetoresistive change ratio) compared with the TMR element with a tunnel barrier layer of Al oxide or Ti oxide as disclosed in U.S. Patent Publication No. 2006/0056115A1.

The tunnel barrier layer of crystalline magnesium oxide is usually formed by deposition of MgO, that is, by an RF sputtering method using a target of MgO. However, if the MgO target is used, it is unavoidable to have uneven resistance among substrates, caused by uneven resistance due to film-thickness distribution of an MgO film on a substrate and by fluctuation of film-deposition speed of the MgO film by the RF sputtering.

In order to solve this problem, it has been attempted that an MgO film is formed by oxidizing a deposited magnesium (Mg) film. However, Mg is material more reactive on oxygen than Al that is generally used as material for the tunnel barrier layer, and therefore easily affected by cleanliness of an oxidation atmosphere, primarily by moisture impurity concentration. As a result, it has been very difficult to stably obtain TMR elements having a high MR ratio.

U.S. Pat. No. 6,710,987 discloses that a tunnel barrier layer is obtained using an alumina (Al₂O₃) film produced with an oxidation process after deposition of an Al film, and that Mg may be used instead of Al. However, an oxidation process with actual use of Mg is not disclosed at all.

### SUMMARY OF THE INVENTION

It is therefore an object of the present invention to provide a manufacturing method of a TMR element, a manufacturing method of a thin-film magnetic head and a manufacturing method of a magnetic memory, whereby it is possible to stably obtain TMR elements having a high MR ratio.

According to the invention, a manufacturing method of a TMR element having a magnetization fixed layer, a magnetization free layer and a tunnel barrier layer sandwiched between the magnetization fixed layer and the magnetization free layer is provided. A fabricating process of the tunnel barrier layer includes a step of depositing a first metallic material film on the magnetization fixed layer or the magnetization free layer, and a step of oxidizing the deposited first metallic material film under an environment with an impurity concentration of 1E-02 or less.

When fabricating the tunnel barrier layer, the atmosphere with an impurity concentration of 1E-02 or less is provided, as the environment in which the deposited first metallic material film is oxidized, to keep high cleanliness. This allows obtaining a higher MR ratio stably even when there is used Mg as a barrier material more reactive on oxygen than Al conventionally used as the barrier material.

It is preferred that the oxidizing step includes oxidizing the deposited first metallic material film under an environment with an impurity concentration of 1E-03 or less.

It is also preferred that the oxidizing step includes oxidizing the deposited first metallic material film by performing flow oxidation in which oxygen (O₂) gas is flown into an oxidation chamber while the gas is discharged by a vacuum pump.

In this case, preferably, the flow oxidation is performed by flowing O₂ gas only. Increment of the O₂ gas flow rate allows improvement of cleanliness of the oxidation atmosphere.

In this case, also preferably, the flow oxidation is performed by flowing O₂ gas and purification gas that does not contribute to the oxidation. By flowing the purification gas that does not contribute to oxidation with O₂ gas by a large quantity, cleanliness of the oxidation atmosphere can be improved. In this case, more preferably, the purification gas may be at least one kind of rare gas nitrogen (N₂) gas and hydrogen (H₂) gas. The rare gas may include helium (He) gas, neon (Ne) gas, argon (Ar) gas, krypton (Kr) gas or xenon (Xe) gas.

It is preferred that the fabricating process of the tunnel barrier layer further includes a step of depositing a second metallic material film on the oxidized metallic film after oxidation of the first metallic material film. The second metallic material film may include the same metallic material as that of the first metallic material film or metallic material primarily containing the same metallic material as that of the first metallic material film.

It is also preferred that the first metallic material film is made of metallic material more reactive on O₂ than Al.

It is further preferred that the first metallic material film is made of Mg or metallic material containing Mg.

According to the invention, also, a manufacturing method of a thin-film magnetic head with a TMR read head element, and a manufacturing method of a magnetic memory with cells using the manufacturing method described above are provided.

Further objects and advantages of the present invention will be apparent from the following description of the preferred embodiments of the invention as illustrated in the accompanying drawings.

### BRIEF DESCRIPTION OF THE DRAWINGS

FIG. 1 is a flow chart illustrating a fabrication process of a thin-film magnetic head in a preferred embodiment according to the present invention;

FIG. 2 is a cross-sectional view schematically illustrating a structure of the thin-film magnetic head produced according to the fabrication process shown in FIG. 1;

FIG. 3 is a flow chart illustrating in more detail a fabrication process of a read head element in the fabrication process shown in FIG. 1;

FIG. 4 is a cross-sectional view schematically illustrating a structure of the read head element part of the thin-film magnetic head shown in FIG. 2;

FIG. 5 is a characteristic diagram illustrating the relationship between a build-up rate and an impurity concentration during an oxidation process;

FIG. 6 is a characteristic diagram illustrating the relationship between an oxidation-process gas flow rate and an MR ratio; and

FIG. 7 is a characteristic diagram illustrating the relationship between an impurity concentration during an oxidation process and an MR ratio.

### DESCRIPTION OF THE PREFERRED EMBODIMENTS

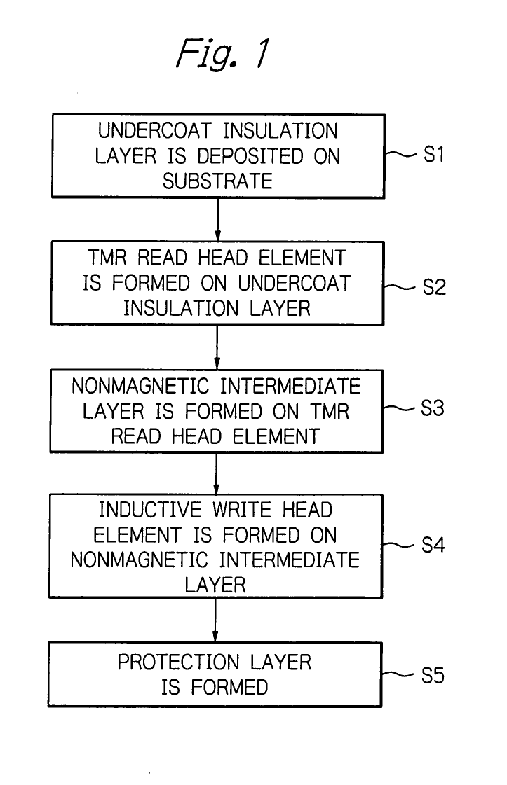

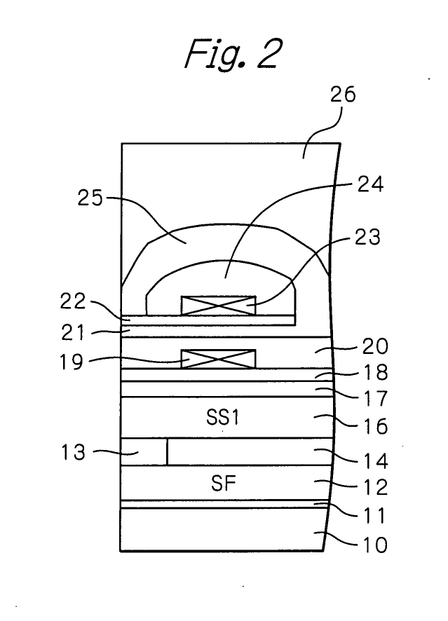

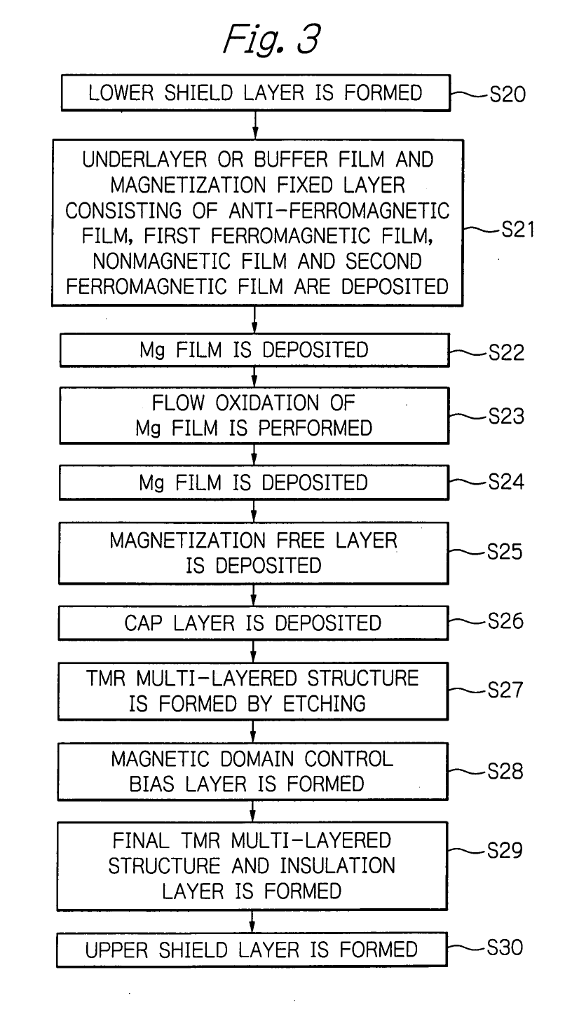

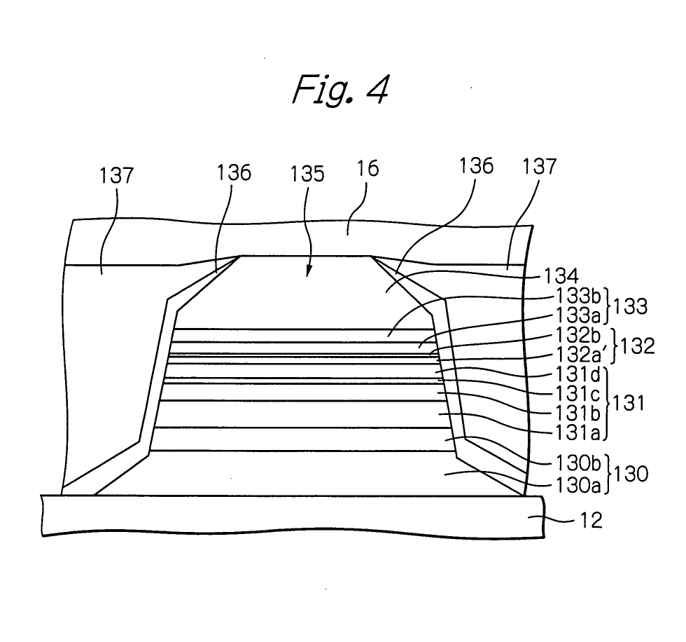

FIG. 1 illustrates a flow of a fabrication process of a thin-film magnetic head in a preferred embodiment according to the present invention, FIG. 2 schematically illustrates a structure of the thin-film magnetic head produced according to the fabrication process shown in FIG. 1, FIG. 3 illustrates in more detail a fabrication process of a read head element part in the fabrication process shown in FIG. 1, and FIG. 4 schematically illustrates a structure of the read head element part in the thin-film magnetic head shown in FIG. 2. It should be noted that FIG. 2 shows a cross section of the thin-film magnetic head on a plane perpendicular to an air bearing surface (ABS) and a track width direction, and FIG. 4 shows a cross section seen from the ABS direction.

As shown in FIGS. 1 and 2, a substrate or wafer 10 made of conductive material such as ALTIC (AlTiC, Al₂O₃—TiC) is first prepared. On the substrate 10, an undercoat insulation layer 11 is formed by deposition of insulation material such as alumina (Al₂O₃) or silicon dioxide (SiO₂) with a thickness of about 0.05-10 μm, using a sputtering method for example (Step S1).

Then, on the undercoat insulation layer 11, a TMR read head element containing a lower shield layer (shield first (SF) layer) 12 used also as a lower electrode layer, a TMR multi-layered structure 13, an insulation layer 14, domain control bias layers 137 (see FIG. 4) and an upper shield layer (shield second (SS1) layer) 16 used also as an upper electrode layer is formed (Step S2). The fabrication process of this TMR read head element will be described in detail later.

Then, on the TMR read head element, a nonmagnetic intermediate layer 17 is formed by deposition of insulation material such as Al₂O₃, SiO₂, aluminum nitride (ALN) or diamond-like carbon (DLC), or metallic material such as Ti, tantalum (Ta) or platinum (Pt) with a thickness of about 0.1-0.5 μm, using for example a sputtering method or a chemical vapor deposition (CVD) method (Step S3). This nonmagnetic intermediate layer 17 is provided for separating the TMR read head element from an inductive write head element formed over the read head.

Thereafter, on the nonmagnetic intermediate layer 17, an inductive write head element is formed (Step S4). This inductive write head element contains an insulation layer 18, a backing coil layer 19, a backing coil insulation layer 20, a main pole layer 21, an insulation gap layer 22, a write coil layer 23, a write coil insulation layer 24 and an auxiliary pole layer 25. Although in this embodiment the inductive write head element with a structure of perpendicular magnetic recording is used, it is apparent that an inductive write head element with a structure of horizontal or in-plane magnetic recording can be used in modifications. Also, as an inductive write head element with a perpendicular magnetic recording structure, various structures other than that shown in FIG. 2 are applicable.

The insulation layer 18 is formed by deposition of insulation material such as Al₂O₃ or SiO₂, on the nonmagnetic intermediate layer 17, using a sputtering method. The surface of the insulation layer 18 may be flattened by for example a chemical mechanical polishing (CMP) method as needed. On the insulation layer 18, the backing coil layer 19 is formed by plating of conductive material such as Cu with a thickness of about 1-5 μm, using a frame plating method for example. The backing coil layer 19 is provided for inducing writing flux to avoid adjacent-track erasure (ATE). The backing coil insulation layer 20 is formed from thermally cured resist material such as novolak resist with a thickness of about 0.5-7 μm, using a photolithography method for example, to cover the backing coil layer 19.

The main pole layer 21 is formed on the backing coil insulation layer 20. This main pole layer 21 functions as a magnetic path for guiding and converging the magnetic flux, induced by the write coil layer 23, into a perpendicular magnetic recording layer of a magnetic disk to be written thereon. The main pole layer 21 is formed by plating of metal magnetic material such as Fe—Al—Si, Ni—Fe, Co—Fe, Ni—Fe—Co, Fe—N, Fe—Zr—N, Fe—Ta—N, Co—Zr—Nb or Co—Zr—Ta, or a multi-layered film of these materials with a thickness of about 0.5-3 μm, using a frame-plating method for example.

The insulating gap layer 22 is formed on the main pole layer 21 by deposition of an insulating film of Al₂O₃ or SiO₂, using sputtering method for example. On the insulating gap layer 22, the write coil insulation layer 24 is formed from thermally cured resist material such as novolak resist with a thickness of about 0.5-7 μm, using a photolithography method for example. Inside the insulation layer 24, the write coil layer 23 is formed by plating of conductive material such as Cu with a thickness of about 1-5 μm, using a frame-plating method for example.

The auxiliary pole layer 25 is formed by plating of metal magnetic material such as Fe—Al—Si, Ni—Fe, Co—Fe, Ni—Fe—Co, Fe—N, Fe—Zr—N, Fe—Ta—N, Co—Zr—Nb or Co—Zr—Ta, or a multi-layered film including these materials with a thickness of about 0.5-3 μm, using a frame-plating method for example to cover the write coil insulation layer 24. This auxiliary pole layer 25 constitutes a return yoke.

Subsequently, the protection layer 26 is formed on the inductive write head element (Step S5). The protection layer 26 is formed by deposition of for example Al₂O₃ or SiO₂, using a sputtering method for example.

Upon finishing the above process, the wafer process of the thin-film magnetic head ends. A manufacturing process of the magnetic head after the wafer process, for example a machining process, is well known, and therefore the description thereof is omitted.

Hereinafter, a detailed description will be given of a fabrication process of the TMR read head element with reference to FIGS. 3 and 4.

First, on the undercoat insulation layer 11, the lower shield layer (SF) 12 used also as a lower electrode layer is formed by plating of metal magnetic material such as Fe—Al—Si, Ni—Fe, Co—Fe, Ni—Fe—Co, Fe—N, Fe—Zr—N, Fe—Ta—N, Co—Zr—Nb or Co—Zr—Ta with a thickness of about 0.1-3 μm, using a frame-plating method for example (Step S20).

Next, on the lower shield layer 12, a first underlayer or buffer film 130a and a second underlayer or buffer film 130b are deposited in this order using a sputtering method for example. The first undercoat layer 130a is formed from for example Ta, hafnium (Hf), niobium (Nb), zirconium (Zr), Ti, molybdenum (Mo) or tungsten (W) with a thickness of about 0.5-5 nm. The second underlayer or buffer film 130b is formed from for example Ni—Cr, Ni—Fe, Ni—Fe—Cr or Ru with a thickness of about 1-5 nm. The first underlayer or buffer film 130a and the second underlayer or buffer film 130b constitute a multi-layered underlayer or buffer film 130. Then, an anti-ferromagnetic film 131a, a first ferromagnetic film 131b, a nonmagnetic film 131c and a second ferromagnetic film 131d are deposited in this order using a sputtering method for example (Step S21). The anti-ferromagnetic film 131a is formed from for example Ir—Mn, Pt—Mn, Ni—Mn or Ru—Rh—Mn with a thickness of about 5-15 nm. The first ferromagnetic film 131b is formed from for example Co—Fe with a thickness of about 1-5 nm. The nonmagnetic film 131c is formed from for example one or more of ruthenium (Ru), rhodium (Rh), iridium (Ir), chromium (Cr), rhenium (Re) and copper (Cu) alloys with a thickness of about 0.8 nm. The second ferromagnetic film 131d of two-layered structure is formed from for example a ferromagnetic film of Co—Fe—B with a thickness of about 1-3 nm and a ferromagnetic film of Co—Fe with a thickness of about 0.2-3 nm. The anti-ferromagnetic film 131a, the first ferromagnetic film 131b, the nonmagnetic film 131c and the second ferromagnetic film 131d constitute a synthetic magnetization fixed layer 131.

Then, on the formed second ferromagnetic film 131d, a metallic film with a thickness of about 0.3-1 nm, more concretely in the embodiment, a metallic film containing Mg or Mg film 132a with a thickness of 0.8 nm is formed, using a sputtering method for example (Step S22).

Thereafter, the stacked film is transferred into an oxidation chamber, and flow oxidation is applied to the Mg film 132a (Step S23). In this flow oxidation, while discharging gas from the oxidation chamber by a vacuum pump, O₂ gas only or O₂ gas with purification gas is induced to perform oxidation process using volumes of process gas (O₂ gas plus purification gas). The purification gas may be at least one kind of, for example, rare gas N₂ gas and H₂ gas. The rare gas may include He gas, Ne gas, Ar gas, Kr gas or Xe gas. This flow oxidation allows formation of an Mg-oxide film 132a′ that constitutes a tunnel barrier layer.

In this embodiment, the flow oxidation is performed under the environment in which impurity concentration during the process is particularly reduced so as to increase an MR ratio (magneto resistance rate). Particularly, when the flow oxidation is performed under the environment with impurity concentration (calculated impurity level, CIL) during the oxidation process of 1E-02 or less, a higher MR ratio can be obtained compared with that of a conventional tunnel barrier layer made of Al-oxide. Furthermore, if the flow oxidation is performed under the environment with the impurity concentration (CIL) during the oxidation process of 1E-03 or less, much higher MR ratio can be obtained. The flow oxidation process will be explained in detail later.

Next, as shown in FIGS. 3 and 4, in order to suppress oxidation, due to the Mg-oxide film 132a′, of a ferromagnetic layer (magnetization free layer) formed on the tunnel barrier layer, a metallic film of the same material as of the Mg film 132a or a metallic film of metallic material containing primarily the same material, that is in the embodiment a Mg film 132b with a thickness of 0.3 nm, is further deposited using a sputtering method for example (Step S24). This process forms a tunnel barrier layer 132.

Alternatively, for the material of the tunnel barrier layer, metallic material more reactive to oxygen than Al may be used instead of Mg.

Then, on the tunnel barrier layer 132 thus formed, a high polarization film 133a of Co—Fe for example with a thickness of about 1 nm, and a soft magnetic film 133b of Ni—Fe for example with a thickness of about 2-6 nm are serially deposited, using a sputtering method for example, to form a magnetization free layer 133 (Step S25).

Then, a cap layer 134 having one layer or two layers or more of Ta, Ru, Hf, Nb, Zr, Ti, Cr or W with a thickness of about 1-20 nm is deposited, using a sputtering method for example (Step S26). According to the above processes, a TMR multi-layered film is formed.

Each film configurations of a magnetic-field sensitive part consisting of the magnetization fixed layer 131, the tunnel barrier layer 132 and the magnetization free layer 133 is not limited to the above-described configuration, but various kinds of material and film thickness may be applicable thereto. For instance, as for the magnetization fixed layer 131, there may be employed the anti-ferromagnetic film plus a single-layer structure of ferromagnetic film or the anti-ferromagnetic film plus a multi-layered structure with other number of layers, other than the anti-ferromagnetic film plus the three-layer structure. Furthermore, as for the magnetization free layer 133, there may be employed a single-layer structure with no high polarization film or a multi-layered structure of more than three layers with a magnetostrictive adjustment film, other than the two-layer structure. Still further, as for the magnetic-field sensitive part, the magnetization fixed layer, the tunnel barrier layer and the magnetization free layer may be stacked in reverse order, that is, stacked in the order of the magnetization free layer, the tunnel barrier layer and the magnetization fixed layer from the bottom. In the latter case, the anti-ferromagnetic film within the magnetization fixed layer is positioned at the top.

Then, a TMR multi-layered structure 135 is formed by etching the TMR multi-layered film (Step S27). This etching process is performed for example by forming, on the TMR multi-layered film, a resist as a resist pattern for a liftoff, and then by applying ion beam of Ar ions through the resist mask to the TMR multi-layered film.

After formation of the TMR multi-layered structure 135, an insulation layer 136 of for example Al₂O₃ or SiO₂ with a thickness of about 3-20 nm, a bias undercoat layer of for example Ta, Ru, Hf, Nb, Zr, Ti, Mo, Cr or W, and a magnetic domain controlling bias layer 137 of fro example Co—Fe, Ni—Fe, Co—Pt or Co—Cr—Pt are serially formed in this order, using sputtering method for example. Thereafter, the resist is peeled off by the liftoff to form a magnetic domain control bias layer 15 (Step S28).

Then, the TMR multi-layered structure 135 is further patterned using a photolithography method for example to obtain a final TMR multi-layered structure 13, and subsequently an insulation layer 14 is deposited using a sputtering method or an ion beam sputtering method for example (Step S29).

Thereafter, on the insulation layer 14 and the TMR multi-layered structure 13, an upper shield layer (SS1) 16 used also as an upper electrode layer of metal magnetic material such as Fe—Al—Si, Ni—Fe, Co—Fe, Ni—Fe—Co, Fe—N, Fe—Zr—N, Fe—Ta—N, Co—Zr—Nb or Co—Zr—Ta, or a multi-layered film containing these materials with a thickness of about 0.5-3 μm is formed, using a frame-plating method for example (Step S30). According to the above-mentioned processes, formation of the TMR read head is completed.

Hereinafter, the flow oxidation process for fabricating the tunnel barrier layer in the embodiment will be described in detail.

An amount of impurity during an oxidation process can be simply represented by a discharge quantity of impurity gas from an oxidation chamber or a buildup rate Q_{ic} and a quantity of the impurity gas in oxidation process gas Q_{ig}. Therefore, if an impurity concentration or calculated impurity level (CIL) during the oxidation process is evaluated by the quantity of impurity contained in a flow rate of the oxidation process gas Q_{gas}, CIL is given by

CIL=(Q_{ic}+Q_{ig})/Q_{gas}

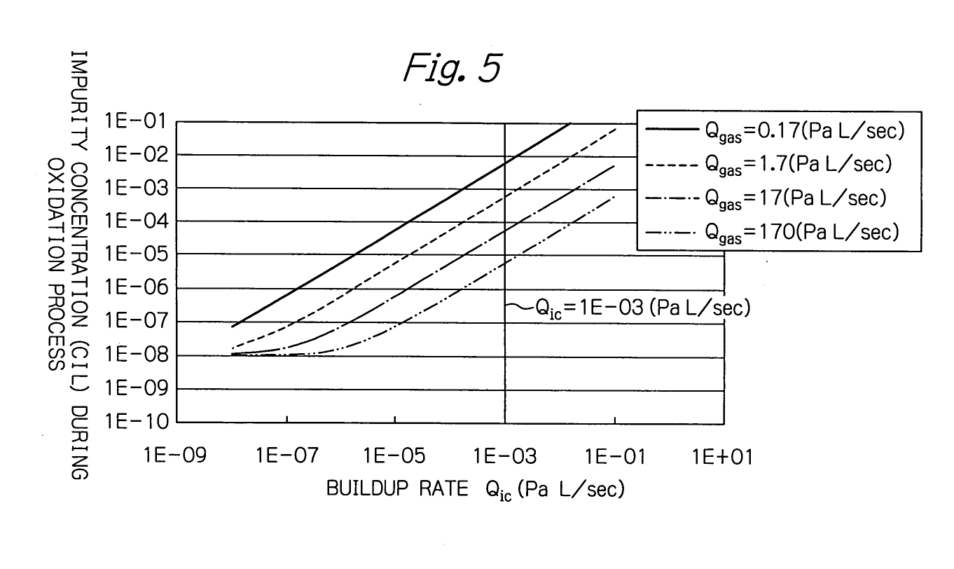

The quantity of the impurity gas in the oxidation process gas Q_{ig} is represented by a product of the flow rate of the oxidation process gas and the purity. For instance, when the purity is 10 ppb, the relationship between the buildup rate Q_{ic} and the impurity concentration (CIL) during the oxidation process is presented as shown in FIG. 5, where the flow rates of the oxidation process gas Q_{gas} (unit: Pa L/sec) are given as a parameter.

As shown in FIG. 5, it is understood that, when the buildup rate Q_{ic} of the oxidation chamber is 1E-03 (Pa L/sec), the impurity concentration (CIL) during the oxidation process decreases monotonically as the flow rate of the oxidation process gas Q_{gas} increases. Accordingly, in order to reduce the impurity concentration (CIL) during the oxidation process, it is effective to increase the flow rate of the oxidation process gas Q_{gas} and to decrease the buildup rate Q_{ic}, and therefore by providing an apparatus configured to meet such characteristics, the present invention can be realized.

However, when the flow rate of the oxidation process gas Q_{gas} is increased, oxidation pressure increases and oxidation speed also increases at the same time. This makes very short time period for oxidation when an element resistance RA of a TMR read head to be produced is low causing difficulty in adequately controlling the oxidation process. In order to avoid such problem, it is effective to enhance a conductance between an oxidation chamber and a vacuum pump, and/or to make the pumping speed of the vacuum pump higher to restrict the oxidation pressure to a predetermined value in spite of a large flow rate. However, this requires a substantial modification of the apparatus. Similarly, reduction of the buildup rate Q_{ic} also needs a modification of the apparatus with the oxidation chamber.

For solving such problem, it is effective to flow a large flow rate of both O₂ gas and “purification gas” that does not affect the oxidation speed and not affect film characteristics even if it is impurity. When the purity of the purification gas is equal to that of O₂ gas, by increasing the flow rate of the purification gas with the flow rate of O₂ gas fixed, the flow rate of the oxidation process gas Q_{gas} can be increased without changing the oxidation speed. That is, reduction of impurity concentration during the oxidation process can be attained without changing oxidation speed, similarly to the case shown in FIG. 5 that the flow rate of the oxidation process gas Q_{gas} is increased.

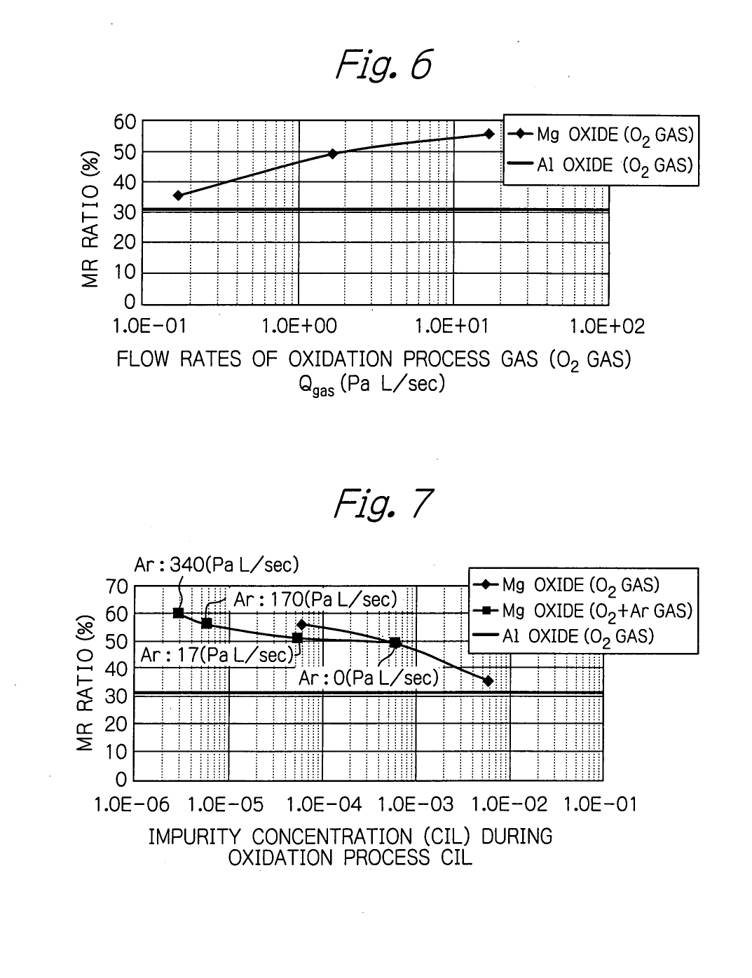

Actually, TMR multi-layered films each having an Mg-oxide barrier layer were fabricated using the same method as of the above-described embodiment. In the flow oxidation process, O₂ gas only was used as one case and O₂ gas with Ar gas (purification gas) was used as the other case, and the MR ratio for each case was measured. Measured results are shown in FIGS. 6 and 7.

FIG. 6 shows the change of MR ratio when the O₂ gas flow rate was changed. Here, the oxidation time was adjusted so as to obtain the same resistance-area-product (RA) when the O₂ gas flow rate was changed. The graph also shows as for comparison an MR ratio of a TMR multi-layered film with an Al-oxide barrier layer and having the similar element resistance RA. The Al-oxide film was fabricated by performing the so-called natural oxidation process in which O₂ gas was induced into an oxidation chamber without vacuuming to get a predetermined pressure.

It is understood from FIG. 6 that the MR ratio tends to increase as the O₂ gas flow rate Q_{gas} increases. In the flow oxidation process for fabricating an Mg-oxide barrier layer, if the O₂ gas flow rate Q_{gas} is 1.0E-01 (Pa L/sec) or more, an Mg-oxide barrier layer having a superior characteristic with a higher MR ratio than that of the Al-oxide barrier layer can be obtained.

Based on the O₂ gas flow rate Q_{gas} shown in FIG. 6, the impurity concentration (CIL) during the process is estimated as shown in FIG. 7 using the aforementioned expression CIL=(Q_{ic}+Q_{ig})/Q_{gas}. FIG. 7 shows a relationship between the impurity concentration (CIL) during the oxidation process and the MR ratio.

It is understood from FIG. 7 that reduction of the impurity concentration (CIL) during the oxidation process permits the MR ratio to be increased. When the impurity concentration CIL is brought to 1E-02 or less, an Mg-oxide barrier layer can have a superior characteristic with a higher MR ratio than that of the Al-oxide barrier layer. Further, by bringing the CIL to 1E-03 or less, much higher MR ratio can be obtained.

FIG. 7 also shows the result when the flow rate of Ar gas used as purification gas was changed to 17, 170 and 340 Pa L/sec while the O₂ gas flow rate is fixed to 1.7 Pa L/sec. As can be found, the MR ratio tends to increase as the Ar gas flow rate increases. This means that it is possible to clean atmosphere of the oxidation process without changing the oxidation speed. Actually, the similar element resistance RA was obtained under a constant oxidation time.

As described above, according to this embodiment, when fabricating the tunnel barrier layer 132, the deposited Mg film 132a is oxidized by flow oxidation, and the Mg film 132a of the same material is deposited on the oxidized Mg-oxide film 132a′. When performing this flow oxidation, a large quantity of O₂ gas only is flown, or a large quantity of Ar gas is flown with O₂ gas, the Ar gas being a purification gas that does not contribute to oxidation, to thereby produce the atmosphere having an impurity concentration CIL of 1E-02 or less, and more preferably of 1E-03 or less to keep high cleanliness. This allows obtaining a higher MR ratio stably even when Mg is used, the Mg being more reactive on oxygen than Al conventionally used as material for the barrier.

The aforementioned embodiment concerns a manufacturing method of a thin-film magnetic head with a TMR read head element. The present invention is similarly applicable to a manufacturing method of a magnetic memory such as an MRAM cell. As is known, each MRAM cell has a TMR structure with a magnetization fixed layer, a tunnel barrier layer, a magnetization free layer and an upper conductive layer acting as a word line serially stacked on a lower conductive layer acting as a bit line.

Many widely different embodiments of the present invention may be constructed without departing from the spirit and scope of the present invention. It should be understood that the present invention is not limited to the specific embodiments described in the specification, except as defined in the appended claims.

1. A manufacturing method of a tunnel magnetoresistive effect element having a magnetization fixed layer, a magnetization free layer and a tunnel barrier layer sandwiched between said magnetization fixed layer and said magnetization free layer, a fabricating process of said tunnel barrier layer comprising the steps of:
depositing a first metallic material film on said magnetization fixed layer or said magnetization free layer; and
oxidizing the deposited first metallic material film under an environment with an impurity concentration of 1E-02 or less.

2. The manufacturing method as claimed in claim 1, wherein said oxidizing step comprises oxidizing said deposited first metallic material film under an environment with an impurity concentration of 1E-03 or less.

3. The manufacturing method as claimed in claim 1, wherein said oxidizing step comprises oxidizing said deposited first metallic material film by performing flow oxidation.

4. The manufacturing method as claimed in claim 3, wherein said flow oxidation is performed by flowing oxygen gas only.

5. The manufacturing method as claimed in claim 3, wherein said flow oxidation is performed by flowing oxygen gas and purification gas that does not contribute to the oxidation.

6. The manufacturing method as claimed in claim 5, wherein said purification gas is at least one kind of rare gas, nitrogen gas and hydrogen gas, said rare gas including helium gas, neon gas, argon gas, krypton gas or xenon gas.

7. The manufacturing method as claimed in claim 1, wherein said fabricating process of said tunnel barrier layer further comprises a step of depositing a second metallic material film on said oxidized metallic film after oxidation of said first metallic material film, said second metallic material film comprising the same metallic material as that of said first metallic material film or metallic material primarily containing the same metallic material as that of said first metallic material film.

8. The manufacturing method as claimed in claim 1, wherein said first metallic material film is made of metallic material more reactive on oxygen than aluminum.

9. The manufacturing method as claimed in claim 1, wherein said first metallic material film is made of magnesium or metallic material containing magnesium.

10. A manufacturing method of a thin-film magnetic head with a tunnel magnetoresistive effect read head element having a magnetization fixed layer, a magnetization free layer and a tunnel barrier layer sandwiched between said magnetization fixed layer and said magnetization free layer, a fabricating process of said tunnel barrier layer comprising the steps of:
depositing a first metallic material film on said magnetization fixed layer or said magnetization free layer; and
oxidizing the deposited first metallic material film under an environment with an impurity concentration of 1E-02 or less.

11. A manufacturing method of a magnetic memory with cells, each cell including a tunnel magnetoresistive effect element having a magnetization fixed layer, a magnetization free layer and a tunnel barrier layer sandwiched between said magnetization fixed layer and said magnetization free layer, a fabricating process of said tunnel barrier layer comprising the steps of:
depositing a first metallic material film on said magnetization fixed layer or said magnetization free layer; and
oxidizing the deposited first metallic material film under an environment with an impurity concentration of 1E-02 or less.
